(19) United States
(12) Patent Application Publication
(10) Pub. No.: US 2013/0335312 A1
(43) Pub. Date: Dec. 19, 2013

(54) INTEGRATION OF THIN FILM SWITCHING DEVICE WITH ELECTROMECHANICAL SYSTEMS DEVICE

(71) Applicant: Teruo Sasagawa, Los Gatos, CA (US)

(72) Inventor: Teruo Sasagawa, Los Gatos, CA (US)

(73) Assignee: QUALCOMM MEMS TECHNOLOGIES, INC., San Diego, CA (US)

(21) Appl. No.: 13/567,845

(22) Filed: Aug. 6, 2012

Related U.S. Application Data
(60) Provisional application No. 61/660,164, filed on Jun. 15, 2012.

(51) Int. Cl. G02B 26/00; G06T 1/00; G06F 3/01; H01L 33/08

(52) U.S. Cl. 345/156; 359/290; 438/34; 345/501; 257/E33.044

(57) ABSTRACT

This disclosure provides systems and methods for thin film switching devices, such as thin film transistors and thin film diodes, which are integrated in a display apparatus. In one aspect, a thin film switching device is positioned on a rear side of an electromechanical systems (EMS) display element formed over a substrate and is in electrical communication with the EMS display element. In another aspect, the thin film switching device is positioned between the EMS display element and the substrate. A planar layer is disposed between the EMS display element and the thin film switching device, with the planar layer having a planar surface.

### CROSS-REFERENCE TO RELATED APPLICATIONS

This patent application claims priority to U.S. Provisional Patent Application No. 61/660,164 filed Jun. 15, 2012 entitled “Integration of Thin Film Switching Device with Electromechanical Systems Device,” and assigned to the assignee hereof. The disclosure of the prior application is considered part of and is incorporated by reference in this patent application

### TECHNICAL FIELD

This disclosure relates generally to electromechanical systems (EMS) devices and more particularly to a thin film switching device integrated display apparatus.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Displays such as interferometric displays (IMODs), liquid crystal displays (LCDs), light-emitting diode (LEDs), bistable displays, and analog displays can have many display elements or pixels. Integrated circuits can be used to control, or electrically switch on and off, the individual display elements. The display elements can be fabricated on a substrate. However, the display elements can have an uneven surface on the substrate due at least in part to the topology of thick film technology. Thus, it can be difficult to fabricate control circuit elements in relation to the display elements because of the uneven surface.

### SUMMARY

The systems, methods and devices of the disclosure each have several innovative aspects, no single one of which is solely responsible for the desirable attributes disclosed herein.

One innovative aspect of the subject matter described in this disclosure can be implemented in a display apparatus. The display apparatus can include a substrate and an electromechanical systems (EMS) display element over the substrate. The EMS display element can have a viewing side facing the substrate and a rear side opposite the viewing side. The display apparatus can also include a thin film switching device positioned on the rear side of the EMS display element, where the thin film switching device is in electrical communication with the EMS display element, and a planar layer disposed between the EMS display element and the thin film switching device, where the planar layer has a planar surface facing the thin film switching device.

In some implementations, the planar layer can include a self-planarizing material. The planar layer can include at least one of a spin-on dielectric, such as spin-on glass, or a high temperature curable polymer.

In some implementations, the thin film switching device includes at least one of a thin film transistor and a thin film diode. In some implementations, the thin film transistor can include amorphous silicon. In some implementations, the thin film transistor can include polysilicon.

In some implementations, the EMS display element can be an IMOD. In some implementations, the IMOD is bistable. In some implementations, the IMOD is analog.

Another innovative aspect of the subject matter described in this disclosure can be implemented in a display apparatus. The display apparatus can include a substrate and an EMS display element over the substrate. The display apparatus can further include a thin film switching device disposed between the EMS display element and substrate, where the thin film switching device is in electrical communication with the EMS display element. The display apparatus can also include a planar layer between the thin film switching device and the EMS display element, where the planar layer has a planar surface facing the EMS display element.

In some implementations, the EMS display element is a reverse IMOD. In some implementations, the thin film switching device includes a thin film transistor.

Another innovative aspect of the subject matter described in this disclosure can be implemented in a method of forming a thin film switching device integrated display apparatus. The method can include forming an EMS display element over an insulating substrate, with the EMS display element having a viewing side facing the insulating substrate and a rear side opposite the viewing side. The method can further include forming a planar layer over the rear side of the EMS display element and forming a thin film switching device over the planar layer.

In some implementations, the method can further include forming a base layer over the planar layer before forming the thin film switching device, wherein the base layer includes silicon dioxide. In some implementations, forming the planar layer can include depositing spin-on glass over the rear side of the EMS display element to form the planar layer.

Another innovative aspect of the subject matter described in this disclosure can be implemented in a display apparatus. The display apparatus can include a substrate and an EMS display element having a viewing side facing the substrate and a rear side opposite the viewing side. The display apparatus can also include a thin film switching device positioned on the rear side of the EMS display element, where the thin film switching device is in electrical communication with the EMS display element. The display apparatus can also include means for planarizing a surface between the EMS display element and the thin film switching device, with the surface facing the thin film switching device.

In some implementations, the planarizing means can include a self-planarizing material. In some implementations, the self-planarizing material includes at least one of a spin-on dielectric and high temperature curable polymer.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9A shows an example of a cross-sectional schematic illustration of a display apparatus with a thin film switching device.

FIG. 9B shows another example of a cross-sectional schematic illustration of a display apparatus with a thin film switching device

FIG. 10A shows an example of a cross-sectional side view of a display apparatus with a thin film switching device.

FIG. 10B shows another example of a cross-sectional side view of a display apparatus with a thin film switching device.

FIG. 10C shows a magnified view of the thin film switching device in FIG. 10B.

FIG. 11 shows an example of a flow diagram illustrating a method of manufacturing a display apparatus.

FIGS. 12A-12F show examples of cross-sectional views illustrating various stages of manufacturing a display apparatus with a thin film switching device.

FIGS. 13A-13I show examples of cross-sectional views illustrating various stages of manufacturing another display apparatus with a thin film switching device.

FIGS. 14A and 14B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, electronic test equipment. Thus, the teachings are not intended to be limited to the implementations depicted solely in the Figures, but instead have wide applicability as will be readily apparent to one having ordinary skill in the art.

Some implementations described herein relate to fabrication of thin film switching devices such as thin film transistors (TFTs) or thin film diodes over an EMS display element having an uneven rear surface. Typically, thin film switching devices can be difficult to fabricate on uneven surfaces when using thick film technology. The thin film switching device can be in electrical communication with and positioned over a rear side of the EMS display element, where a planar layer is disposed between the EMS display element and the thin film switching device such that the thin film switching device is positioned over a planar surface of the planar layer.

Particular implementations of the subject matter described in this disclosure can be implemented to realize one or more of the following potential advantages. Providing a planar layer over an uneven surface of a display element creates a planar surface for ease of fabricating a thin film switching device such as a TFT. The planar surface can provide for several different types of TFTs to be fabricated over the display element, including TFTs where the thickness uniformity and the surface flatness are important, including amorphous silicon (a-Si) TFTs and low temperature poly-silicon (LTPS) TFTs. In addition, the planar surface allows for the thin film switching device to be formed on the rear side of the display element, which can improve the fill factor of the display apparatus. Moreover, with a planar surface over an uneven surface of the display element, the size of the thin film switching device can be as large as the display element's area, or the number of thin film switching devices can be as many as the devices fill up the display element's area.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

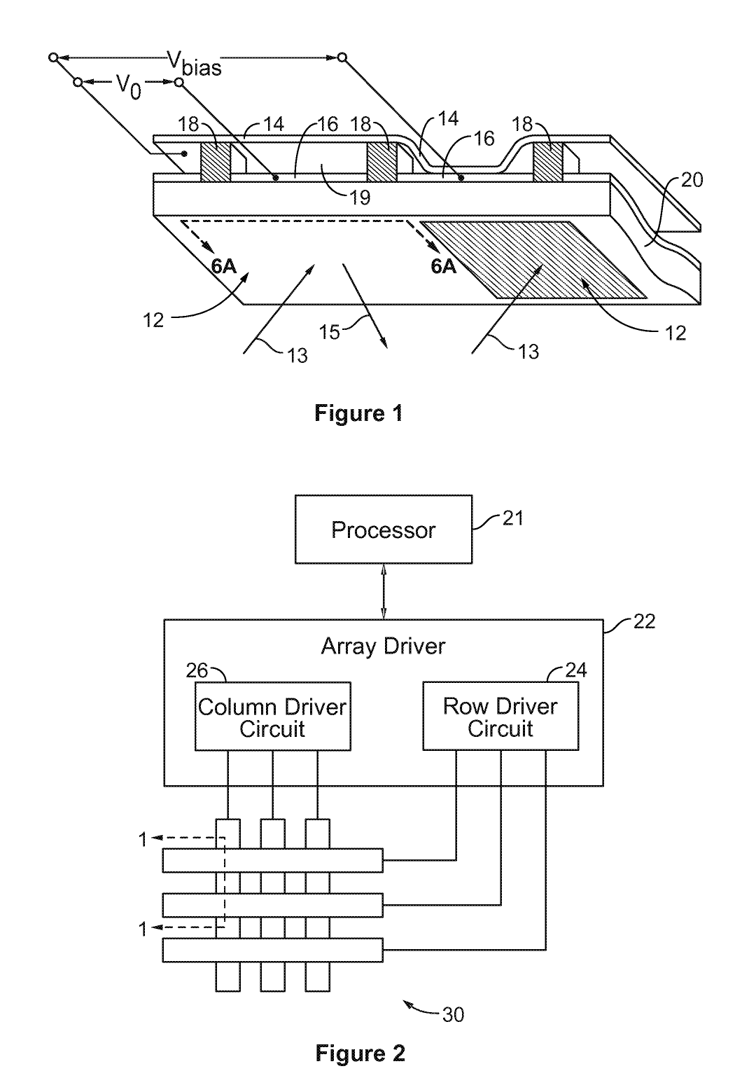

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

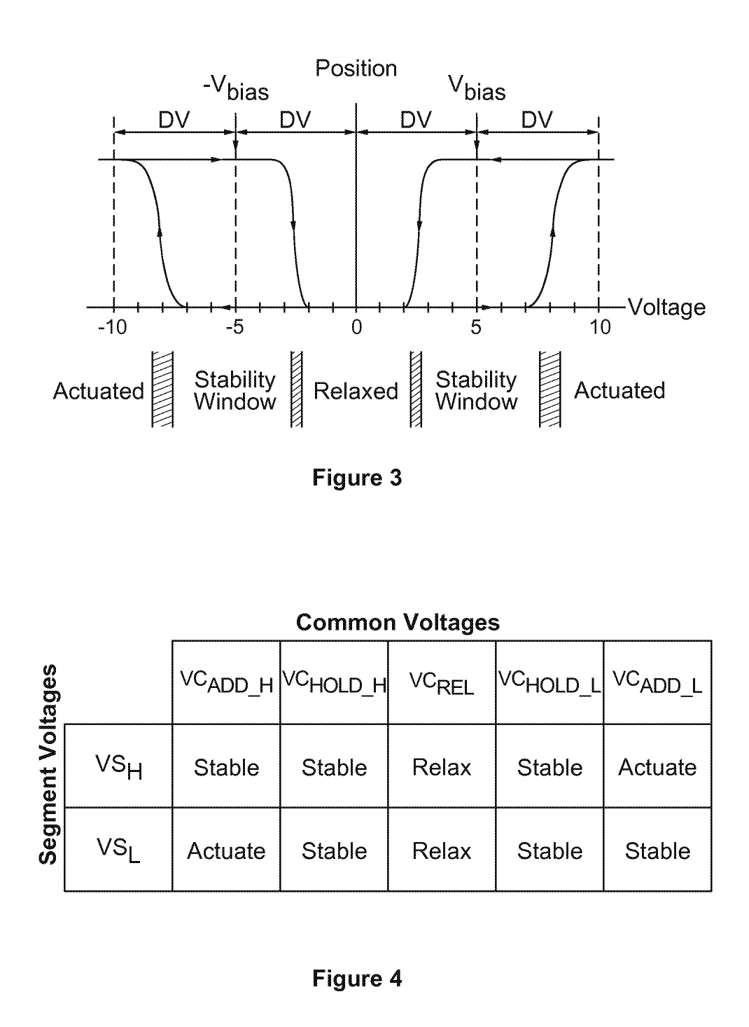

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10 volts, however, the movable reflective layer does not relax completely until the voltage drops below 2 volts. Thus, a range of voltage, approximately 3 to 7 volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10 volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7 volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

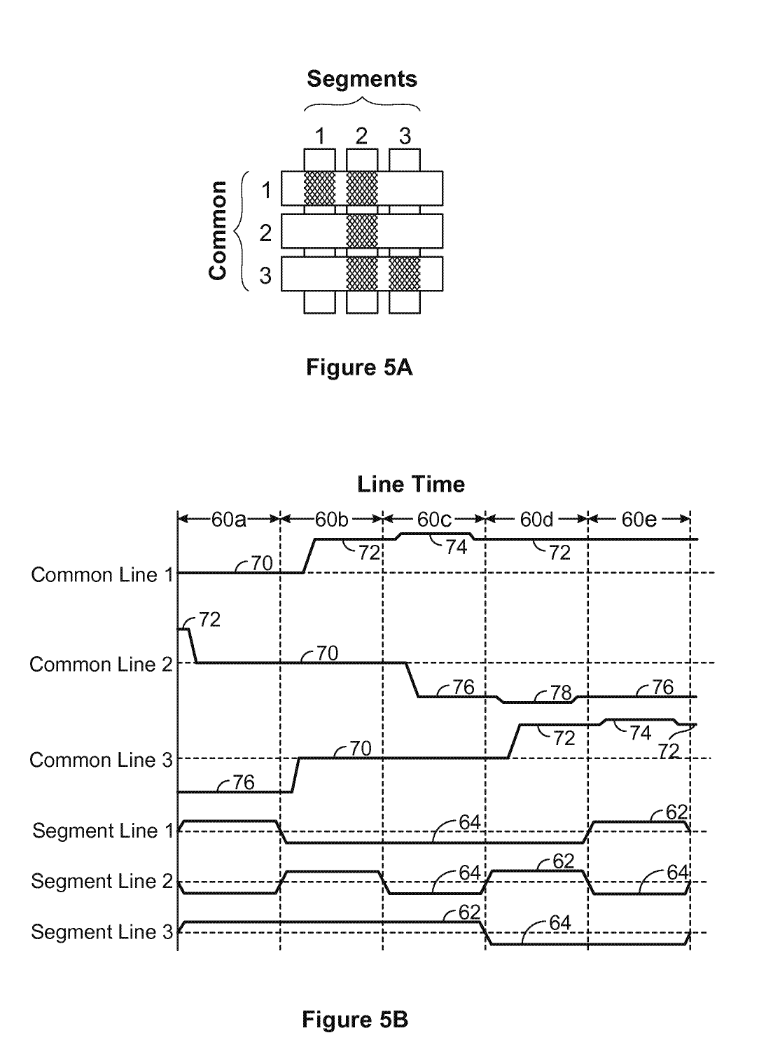

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a, a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}−relax and VC_{HOLD}_{_{—}}_{L}−stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

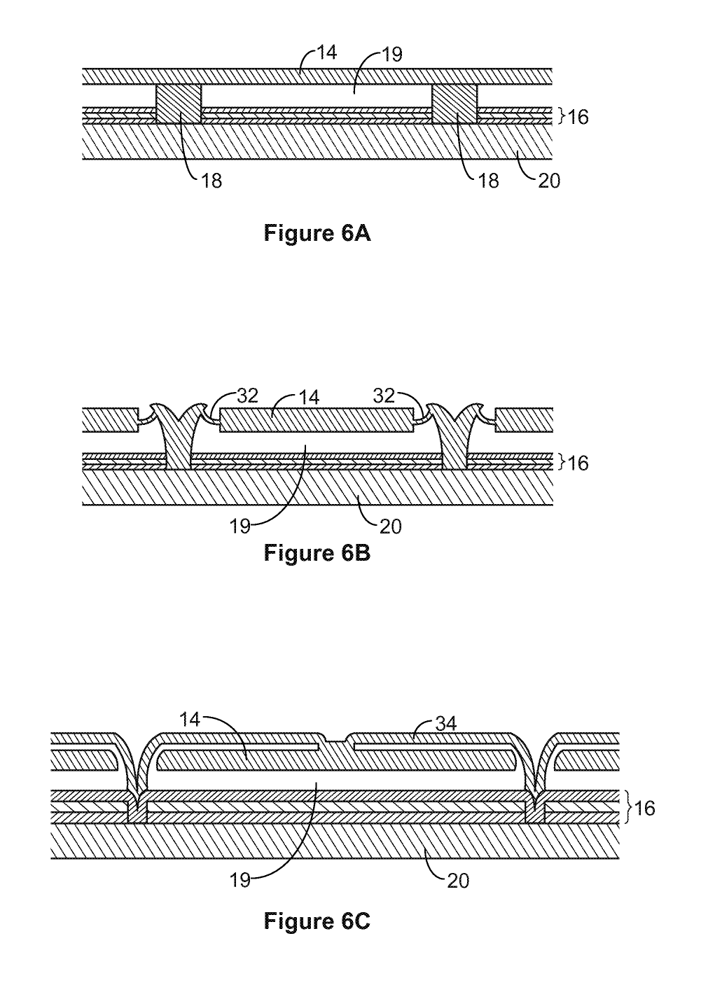

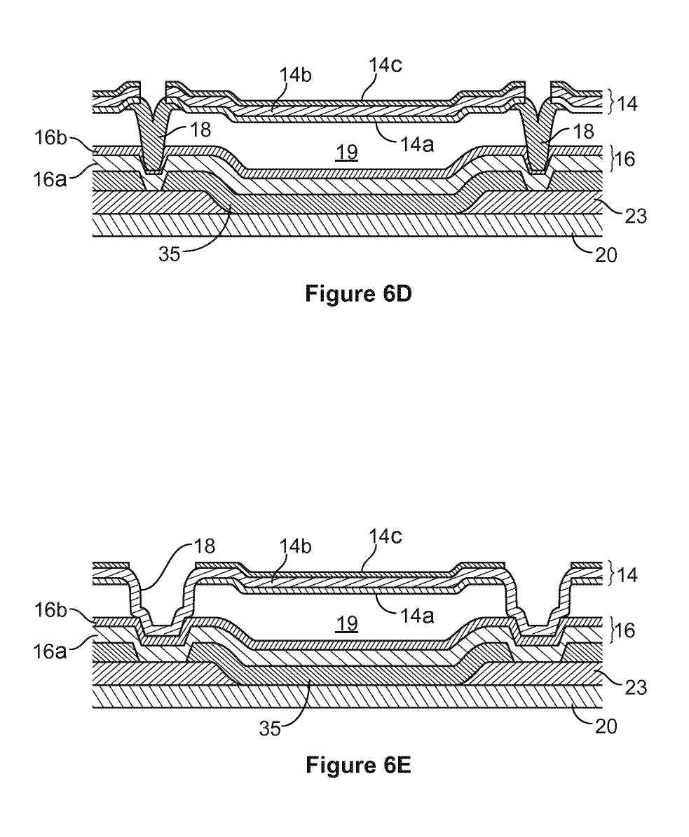

The details of the structure of interferometric modulators that operate in accordance with the principles set forth above may vary widely. For example, Figures 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, an SiO₂ layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self-supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

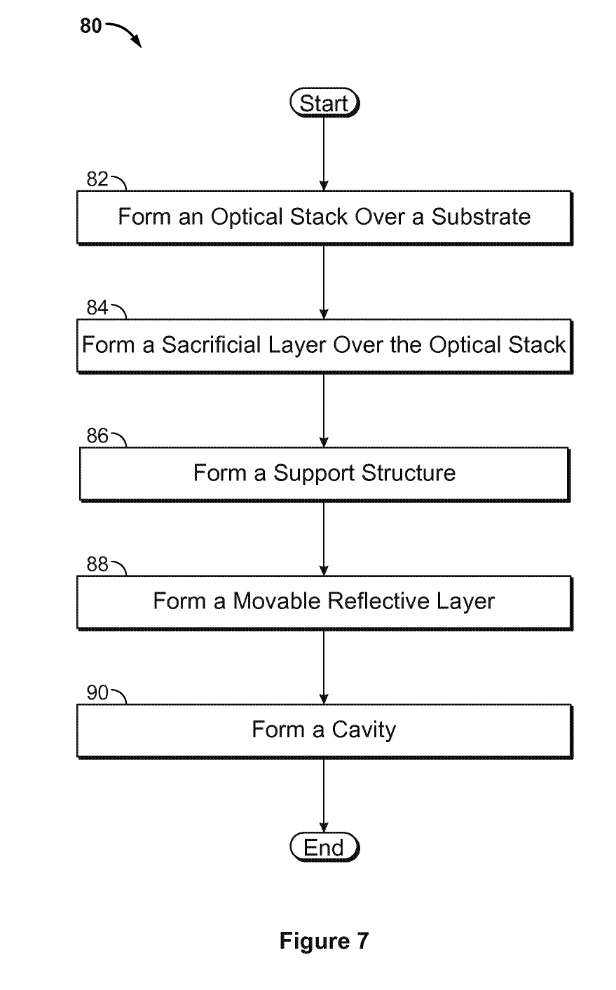

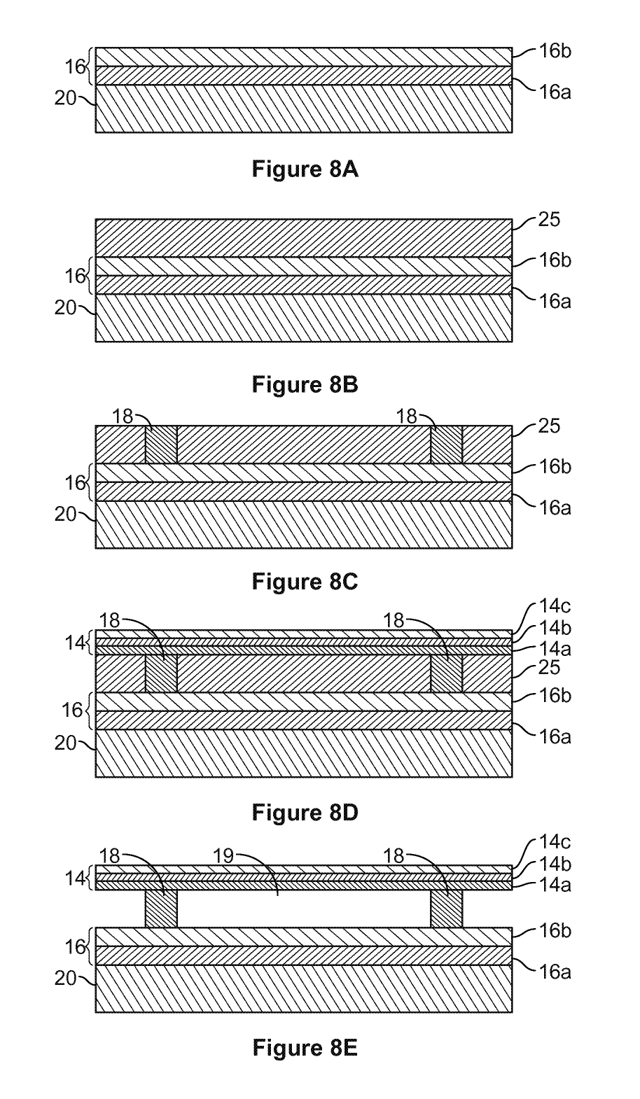

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning to remove portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition processes, e.g., reflective layer (e.g., aluminum, aluminum alloy) deposition, along with one or more patterning, masking, and/or etching processes. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 also may be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other combinations of etchable sacrificial material and etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

Integrated circuits can be used to control individual display elements of displays such as IMODs, LCDs, LEDs, bi-stable displays, or analog displays. Integrated circuits can include thin film switching devices such as thin film transistors (TFTs) or thin film diodes. The thin film switching devices can electrically communicate with the display elements. For example, the thin film switching devices can serve to switch the display elements by providing analog or digital signals to the display elements.

In display devices such as an IMOD, the TFTs can be integrated with the IMOD display elements or pixels. Various IMOD architectures can integrate the TFT in various positions. In some implementations, the TFT can be formed on a substrate of an IMOD. However, the TFT can obstruct viewing and reduce the viewable area in such IMOD architectures. In some implementations, the TFT can be formed adjacent to the IMOD display element. Devices in which the IMOD display elements are adjacent to the TFTs can be characterized by a reduced fill factor. The fill factor of an IMOD can be defined as the ratio of optically active area of the IMOD relative to the total area of the IMOD. To increase the fill factor, and to avoid obstruction of the viewable area, the TFT can be fabricated on a rear side of the IMOD rather than adjacent to the IMOD or on the substrate.

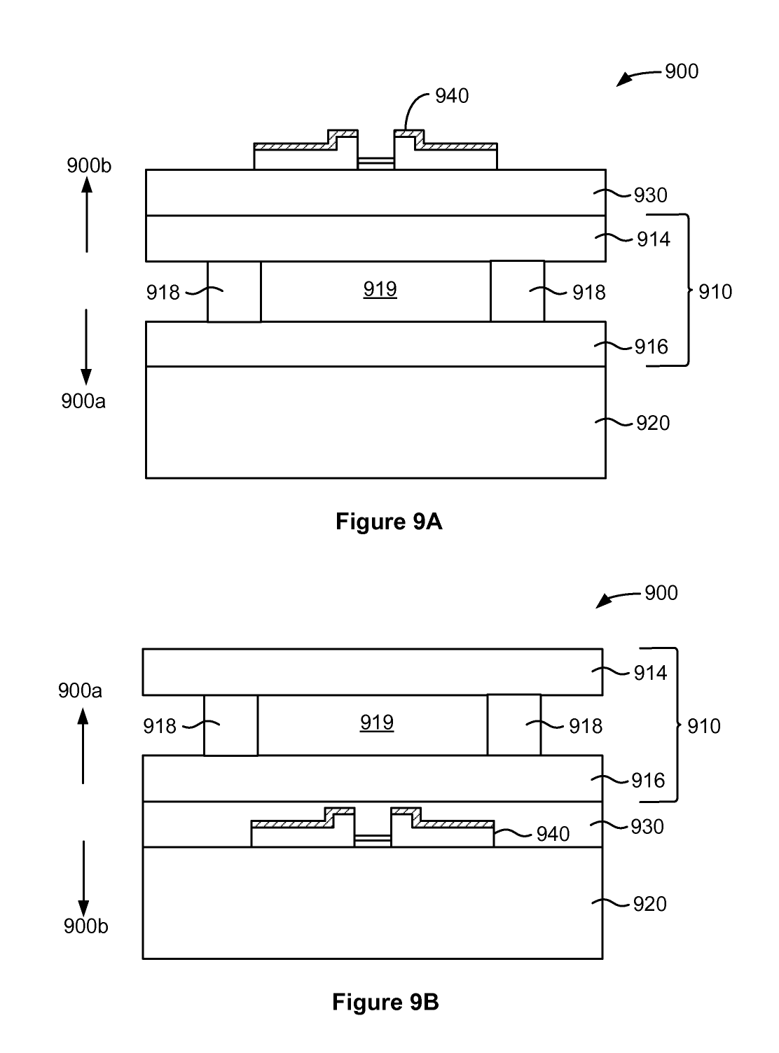

FIG. 9A shows an example of a cross-sectional schematic illustration of a display apparatus with a thin film switching device. The display apparatus 900 can include an electromechanical systems (EMS) display element 910 over a substrate 920. The EMS display element 910 can be one of a reflective display element, a transmissive display element, or a self-emitting element. In some implementations, the EMS display element 910 is a reflective display element such as an IMOD. The EMS display element 910 can have a viewing side 900a facing the substrate 920 and a rear side 900b opposite the viewing side 900a.

In the example in FIG. 9A, the display apparatus 900 can include a substrate 920. In some implementations, the substrate 920 can be transparent. The EMS display element 910 can be formed over the substrate 920, and can include an optical stack 916, support posts 918, an optical gap 919, and a movable reflective layer 914. In the illustrated implementation, the optical stack 916 is formed on the substrate 920. One having ordinary skill in the art will readily understand that the figures are simplified schematics and additional layers, such as underlying or intervening buffer layers, black mask layers, and bussing layers, may be present. The optical stack 916 can include multiple layers, such as a dielectric layer formed over an absorber layer. In addition, the optical stack can include a conductor layer, such as ITO. The IMOD can include a movable reflective layer 914 above the optical stack 916, with an optical gap 919 between the movable reflective layer 914 and the optical stack 916. The movable reflective layer 914 can include one or more layers, such as a reflective layer, a mechanical layer, and a conductor layer. In addition, the movable reflective layer 914 can be supported by posts 918 positioned over the optical stack 916. The movable reflective layer 914 can be configured to actuate towards the optical stack 916 when a voltage is applied.

The display apparatus 900 can further include a thin film switching device 940 positioned on the rear side 900b of the EMS display element 910. The thin film switching device 940 can include a TFT or a thin film diode that is in electrical communication with the EMS display element 910. In some implementations, the thin film switching device 940 can provide a signal to the EMS display element 910 to actuate the movable reflective layer 914 between two or more distances from the optical stack 916. In a bistable IMOD, the movable reflective layer 914 can be configured to move between two different distances from the optical stack 916. In an analog IMOD, the movable reflective layer 914 can be configured to move to three or more different distances from the optical stack 916. In other words, the reflective layer 914 can move and stop at three or more different positions from the optical stack 916.

A planar layer 930 can be disposed between the EMS display element 910 and the thin film switching device 940. The planar layer 930 can have a planar surface facing the thin film switching device 940. In some implementations, the planar layer 930 can include a self-planarizing material, such as a high-temperature curable polymer or spin-on dielectric.

FIG. 9B shows another example of a cross-sectional schematic illustration of a display apparatus with a thin film switching device. In some implementations of the display apparatus 900, the EMS display element 910 can have a viewing side 900a opposite the substrate 920 and a rear side 900b opposite the viewing side 900a, such as in an “inverted” IMOD or “reverse” IMOD architecture. In such architectures, the thin film switching device 940 is formed over the substrate 920. The thin film switching device 940 can be a TFT in electrical communication with the EMS display element 910. The planar layer 930 can be formed over the thin film switching device 940. In some implementations, the planar layer 930 has a planar surface facing the EMS display element 910. The optical stack 916 can be formed over the planar layer 930. The movable reflective layer 914 can be formed over the optical stack 916 and supported by posts 918.

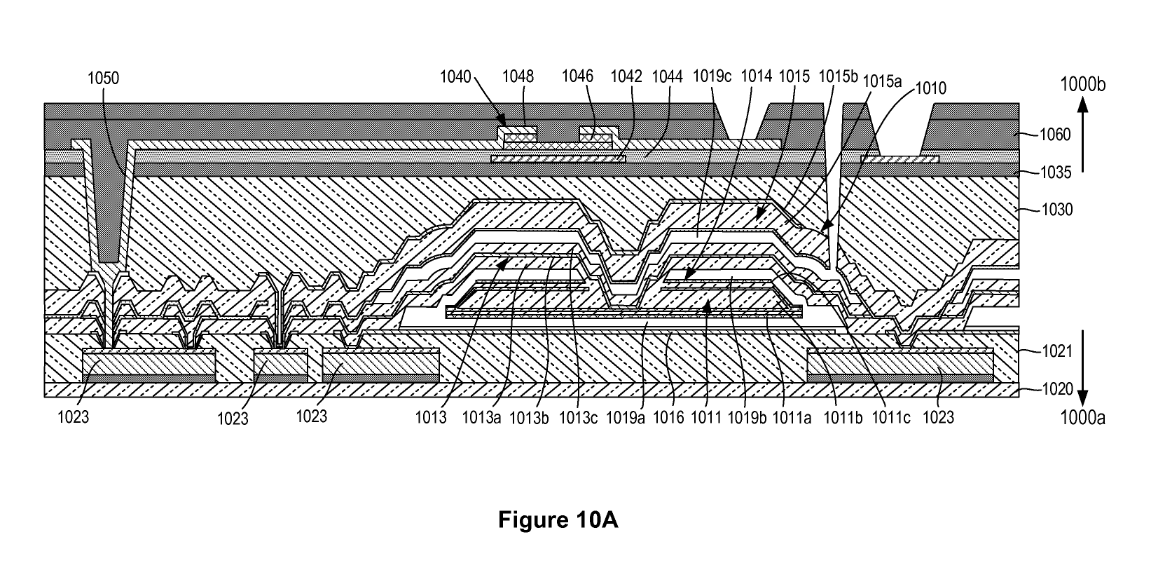

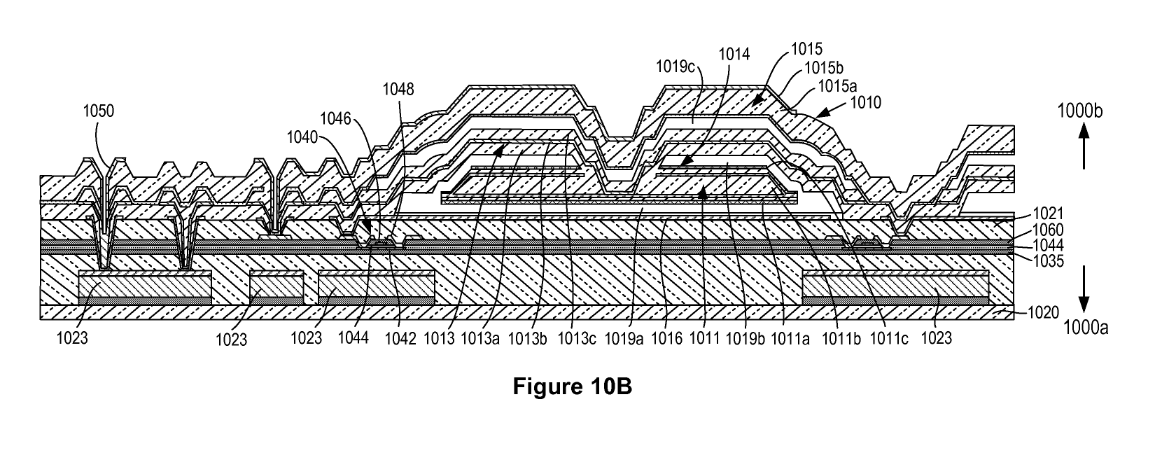

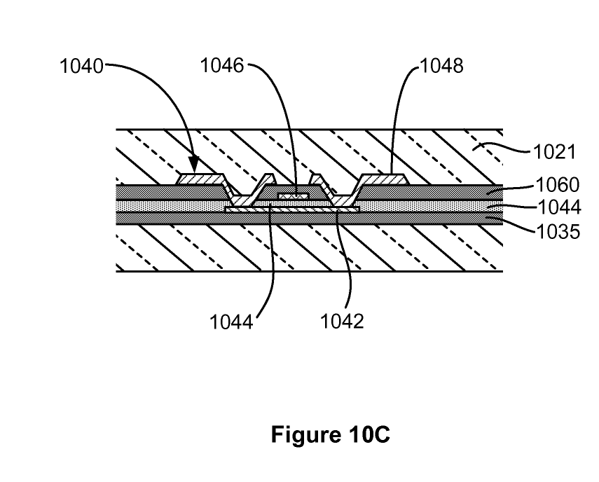

FIG. 10A shows an example of a cross-sectional side view of a display apparatus with a thin film switching device. The display apparatus 1000 can include a substrate 1020 with an IMOD display element 1010 formed over the substrate 1020. In some implementations, the IMOD display element 1010 can have a viewing side 1000a facing the substrate 920 and a rear side 1000b opposite the viewing side 1000a. The IMOD display element 1010 can have an uneven surface or topography. The uneven surface topography can be at least in part a result of thick film deposition and overlap of layers. It can be difficult to fabricate thin film switching devices such as a TFT on the rear side 1000b of the IMOD display element 1010 because of the uneven surface topography.

The display apparatus 1000 can be part of an analog IMOD (AIMOD). In an AIMOD, a pixel's reflective color is determined by the gap spacing between an absorbing layer (e.g., optical stack 1016) and a reflecting layer (e.g., reflective layer 1014), and the reflecting layer is movable between a plurality of positions relative to the absorbing layer. Accordingly, the size of the gap between the reflecting layer and the absorbing layer can be varied. Depending on the position of the reflecting layer, different wavelengths of light are reflected back through the substrate 1020, which gives the appearance of different colors.

The display apparatus 1000 can include a substrate 1020. The substrate 1020 can be a transparent substrate that is made of glass, plastic, or other material. In some implementations, the substrate 1020 can be made of spin-on dielectric material such as spin-on glass material. In some implementations, the substrate 1020 can be made of an epoxy, such as a UV curable or thermally curable epoxy that is flowable when dispensed. In some implementations, the substrate can include a borosilicate glass, a soda lime glass, quartz, Pyrex™, or other suitable material.

As illustrated in the example in FIG. 10A, the IMOD display element 1010 can include black mask structures 1023 over the substrate 1020. The black mask structures 1023 can be conductive and configured to function as electrical bussing layers. The black mask structures 1023 can include one or more layers of materials, such as Mo, MoCr, SiO₂, aluminum copper (AlCu), and/or aluminum oxide (Al₂O₃).

In some implementations, a planarization layer 1021 can be formed over the black mask structures 1023 and substrate 1020. The planarization layer 1021 can include a spin-on dielectric, such as spin-on glass, that can serve to substantially planarize the surface for subsequent formation of layers in the IMOD display element 1010. Other examples of the planarization layer 1021 can include a curable polymer such as polyimide. The planarization layer 1021 can also function to electrically isolate the conductive layers of the black mask structures 1023 from the conductive layers of the optical stack 1016.

The IMOD display element 1010 can also include an optical stack 1016. The optical stack 1016 can include one or more layers, such as an absorbing layer, an optical layer, and/or a conductive layer. In some implementations, the absorbing layer can include a layer of material including MoCr with a thickness ranging from approximately 2 nm to 10 nm. The absorbing layer can be configured to partially absorb and partially reflect light. In some implementations, the absorbing layer can also be electrically conductive. Additionally, the optical layer can include sub-layers of, such as, a transparent sub-layer of SiO₂ and an etch stop sub-layer of Al₂O₃, with the optical layer having a thickness between about 4 nm and about 10 nm. In addition, the optical stack 1016 can be patterned into individual and parallel strips that form the rows of the display apparatus 1000.

Still referring to the example in FIG. 10A, the IMOD display element 1010 can include a movable reflective structure 1014 between the optical stack 1016 and a stationary element 1015. A first gap 1019a can separate the movable reflective structure 1014 from the optical stack 1016. The movable reflective structure 1014 can include a reflector 1011 and a deformable layer 1013. As illustrated, the reflector 1011 can be separated from the deformable layer 1013 by a second gap 1019b. A third gap 109c can separate the movable reflective structure 1014 from the stationary element 1015. Because the reflector 1011 is reflective and not transmissive, light does not propagate through the reflector 1011 and into the second gap 1019b. Hence, the IMOD display element 1010 may be configured to interferometrically modulate light with the first gap 1019a, and not with the second gap 1019b or the third gap 1019c.

The reflector 1011 is coupled to the deformable layer 1013 at a center portion of the movable reflective structure 1014. In this configuration, the optical properties of the movable reflective structure 1014 can be decoupled from its mechanical properties. During actuation, the deformable layer 1013 moves in response to an applied voltage. Due to the separation of the reflector 1011 from the deformable layer 1013, bending the deformable layer 1013 does not translate into bending of the reflector 1011. Rather, the reflector 1011 can be moved vertically across the first gap 1019a relative to the optical stack 1016, while remaining substantially planar. Additionally, since the bending for actuation is undertaken by the deformable layer 1013, the reflector 1011 does not suffer distortion from bending in the peripheral regions. Accordingly, the optically active area of the reflector 1011 can be increased, resulting in a higher fill factor.

In some implementations, the reflector 1011 can include a plurality of sub-layers 1011a, 1011b, and 1011c. For example, a dielectric layer 1011b can be positioned near the center of the reflector 1011. In some implementations, the dielectric layer 1011b can have a thickness between about 2500 Å and about 10000 Å, or about 5000 Å, providing rigidity to the reflector 1011. The dielectric layer 1011b can be made of SiO₂, SiN, SiON, or other suitable dielectric material.

In some implementations, a first mirror stack 1011a and a second mirror stack 1011c can be arranged below and above the dielectric layer 1011b, respectively. In some implementations, each of the first mirror stack 1011a and the second mirror stack 1011c can have materials and thicknesses that are substantially identical. For example, the first mirror stack 1011a can have a reflective material such as titanium oxide (TiO₂) with a thickness of about 285 Å and facing the optical stack 1016, a dielectric material such as SiON or SiO₂ with a thickness of about 650 Å, and an electrically conductive material such as AlCu with a thickness of about 300 Å. The second mirror stack 1011c can be symmetrically identical with the first mirror stack 1011a, and can also have a reflective material of TiO₂ with a thickness of about 285 Å, a dielectric material of SiON or SiO₂ with a thickness of about 650 Å, and an electrically conductive material of AlCu with a thickness of about 300 Å. Such symmetrical construction can provide increased structural rigidity so as to improve control of the shape of the mirror in the reflector 1011. The symmetrical construction can also balance the stresses that can be caused by a mismatch of the coefficients of thermal expansion (CTEs) of the various materials, so that the subsequent layers can be substantially planar.

In some implementations, the deformable layer 1013 can include a plurality of sub-layers. As illustrated, the deformable layer 1013 can include a metal layer 1013b between a lower deformable layer 1013a and an upper deformable layer 1013c. In some implementations, the metal layer 1013b can include a metal such as AlCu, with a thickness between about 100 Å and about 500 Å, such as about 300 Å. The metal layer 1013b can be electrically connected to at least the first mirror stack 1011a. Additionally, the metal layer 1013b can be electrically connected to one of the black mask structures 1023. The lower deformable layer 1013a and the upper deformable layer 1013c can have materials and thicknesses that are substantially identical. For example, the upper and lower deformable layers can include SiO₂, SiN, SiON, or other suitable dielectric materials, and can each have a thickness between about 1000 Å and about 5000 Å. Such relatively thick upper and lower deformable layers can provide sufficient structural support to the deformable layer 1013, while retaining flexibility for the deformable layer 1013 to respond to an electric field. The symmetric construction can also balance the stresses in the deformable layer 1013.

Because the deformable layer 1013 is separated from the reflector 1011 by a second gap 1019b, the deformable layer 1013 can be hidden from the viewing side 1000a of the IMOD display element 1010, and the mechanical properties of the deformable layer 1013 can be adjusted independently from the optical properties of the reflector 1011. Accordingly, the materials and thicknesses for the respective sub-layers of the deformable layer 1013 can be selected to achieve desired mechanical characteristics, while the materials and thicknesses for the respective sub-layers of the reflector 1011 can be selected to achieve desired optical characteristics. This allows for wider design freedom to vary the properties of the deformable layer 1013 and the reflector 1011, depending on the application.

In some implementations, a stationary element 1015 can be positioned over the deformable layer 1013 with a third gap 1019c between the stationary element 1015 and the deformable layer 1013. The stationary element 1015 can include a plurality of sub-layers. For example, the stationary element 1015 can include a dielectric layer 1015a made of one or more transparent materials such as SiO₂ and SiON, and an electrode 1015b formed over the dielectric layer 1015a. The electrode 1015b can include an electrically conductive material such as AlCu. In some implementations, the stationary element 1015 can further include another dielectric layer (not shown) over the electrode 1015b, which can serve to increase mechanical support to a planar layer 1030 and to stabilize the electrode 1015b. In some implementations, the stationary element 1015 can have a thickness between about 1 μm and about 10 μm. Because of the relatively large thickness of the stationary element 1015, the resulting IMOD display element 1010 can have increased surface unevenness on the rear side 1000b.

A planar layer 1030 can be formed over the stationary element 1015 in the example in FIG. 10A. In some implementations, the planar layer 1030 can include a self-planarizing material, such as a curable polymer or a spin-on dielectric material. In some instances, the spin-on dielectric material can be a thick spin-on glass layer, and the planar layer 1030 can have a thickness between about 1 μm and about 2 μm. Thickness can generally refer to the thickest part of the planar layer 1030. In some other instances, a curable polymer can be a high-temperature curable polymer such as polyimide, and the planar layer 1030 can have a thickness between about 1 μm and about 5 μm. However, the planar layer 1030 can be thinner in implementations where the stationary element 1015 includes another dielectric layer over the electrode 1015b that is relatively thick. In some implementations, the planar layer 1030 can be any suitable insulating material that can be substantially planarized by an appropriate planarization method such as lapping, grinding, chemical mechanical planarization (CMP), or anisotropic dry etching. In instances when the planar layer 1030 includes a planarized insulating material, the planar layer 1030 can have a thickness greater than when the planar layer 1030 includes a self-planarizing material. For example, a planar layer formed of a planarized insulating material can have a thickness between about 1 μm and 5 μm. The planar layer 1030 can provide a smooth flat surface so that fabrication of a thin film switching device 1040 over the planar layer 1030 can be achieved.

In some implementations, a base layer 1035 of oxide or nitride, such as SiO₂, aluminum oxide (AlOₓ), silicon nitride (SiNₓ), or silicon oxynitride (SiON), can be formed over the planar layer 1030. The base layer 1035 can serve as a base oxide layer for the subsequent formation of TFTs. The base layer 1035 can serve to provide a moisture barrier to protect the IMOD display element 1010 from the external environment and can improve the outgassing properties of the underlying planar layer 1030. The base layer 1035 can be conformally deposited so as to be substantially planar with the planar layer 1030.

In some implementations, the base layer 1035 can be a low quality oxide. The quality of the oxide describes the way that the oxide grows and can depend on the function of the layer. A low quality oxide can have a high deposition rate, a high etch rate, a low breakdown voltage, a high leakage current, and better uniformity than a high quality oxide. A high quality oxide can have a low deposition rate, a low etch rate, a high breakdown voltage, a low leakage current, and less uniformity than a low quality oxide.

At least one thin film switching device 1040 can be formed over the base layer 1035 of the display apparatus 1000. The thin film switching device 1040 can be a TFT formed on the rear side 1000b opposite the viewing side 1000a of the IMOD display element 1010. Because the planar layer 1030 provides a smooth flat surface, the TFT 1040 can be fabricated over the IMOD display element 1010 so as to be aligned with and in close proximity to the IMOD display element 1010. Many different types of TFTs 1040 can be fabricated over the base layer 1035, including but not limited to an a-Si TFT, a poly-Si TFT, a polymer semiconductor TFT, and an oxide semiconductor TFT such as indium gallium zinc oxide (IGZO) or indium zinc oxide (IZO) TFT.

The TFT device is a field-effect transistor that includes a source, a drain, and a channel in a semiconductor material. In some implementations, as illustrated in the example in FIG. 10A, the TFT 1040 can be a bottom gate TFT such as an a-Si TFT that includes a gate metal 1042 formed on the base layer 1035. In other implementations, the TFT 1040 can be a top gate TFT such as a poly-Si TFT. The poly-Si TFT can be formed by depositing a thin film of a-Si and exposing the a-Si to an excimer laser. In some implementations, the poly-Si TFT can be smaller than the a-Si TFT. In certain implementations of the a-Si TFT, the gate metal 1042 can include Cr, Al, Cu, Mo, tantalum (Ta), neodymium (Nd), tungsten (W), titanium (Ti), and other suitable metals.

The TFT 1040 can further include a gate insulator 1044 deposited over the base layer 1035 and over the gate metal 1042. The gate insulator 1044 can include any number of different dielectric materials known in the art, such as an oxide. In some implementations, the gate insulator 1044 can include a high quality oxide.

The TFT 1040 can further include a semiconductor layer 1046 over the gate insulator 1044. In some implementations, the semiconductor layer 1046 can include a bilayer of doped n-type a-Si formed over intrinsic a-Si. For example, the doped n-type a-Si layer can be doped with phosphorus. The doped n-type a-Si layer can provide improved electrical contact with a source/drain metal 1048 for the semiconductor layer 1046. The source/drain metal 1048 can be formed over portions of the semiconductor layer 1046 and the gate insulator 1044. In some implementations, the source/drain contact 1048 can include a tri-layer of Mo/Al/Mo. Alternatively, Mo can be substituted with other metals such as Ta, W, or Ti. In some implementations, a via structure 1050 can provide an electrically conductive pathway connecting the source/drain metal 1048 with at least one of the black mask structures 1023. Hence, the TFT 1040 can be in electrical communication with the IMOD display element 1010 and hidden from the viewing side 1000a. A passivation layer 1060 can be formed over the TFT 1040 and can serve as a layer that protects the TFT 1040 from the external environment. The passivation layer 1060 can include any number of different dielectric materials, such as an oxide. In some implementations, the passivation layer 1060 can include a low quality oxide. In some implementations, the passivation layer 1060 can include a layer of SiO₂ over a layer of SiN or SiON.

FIG. 10B shows another example of a cross-sectional side view of a display apparatus with a thin film switching device. In some implementations as illustrated in the example in FIG. 10B, the display apparatus 1000 can include the thin film switching device 1040 on the viewing side 1000a of the IMOD display element 1010. The IMOD display element 1010 can include black mask structures 1023 formed over the substrate 1020 that can produce an uneven surface or topography. As such, the planarization layer 1021 can serve to provide a smooth flat surface so that the fabrication of the thin film switching device 1040 can be achieved between the black mask structures 1023 and the IMOD display element 1010.

The thin film switching device 1040 can be a TFT formed behind any of the black mask structures 1023 so as to avoid visibility through the viewing side 1000a.

FIG. 10C shows a magnified view of the thin film switching device in FIG. 10B. The thin film switching device 1040 can be formed over the base layer 1035. The base layer 1035 can be an oxide, such as a low quality oxide. As discussed earlier herein, many different types of TFTs can be fabricated, including but not limited to an a-Si TFT, a poly-Si TFT, a polymer semiconductor TFT, and an oxide semiconductor TFT such as an IGZO or IZO TFT. In the example in FIGS. 10B and 10C, the TFT can be an a-Si TFT with a semiconductor layer 1046, a gate insulator 1044, a gate metal 1042, and a source/drain metal 1048. The semiconductor layer 1046 can include a layer of a-Si over the base layer 1035. The gate insulator 1044 can be deposited over the base layer 1035 and over the semiconductor layer 1046. In some implementations, the gate insulator 1044 can be an oxide, such as a high quality oxide. The gate metal 1042 can be deposited over the gate insulator 1044, and can include Cr, Cu, Al, Mo, Ti, Ta, or alloys thereof. A passivation layer 1060 can be formed over the gate insulator 1044 and over the gate metal 1042. In some implementations, the passivation layer 1060 can include an oxide, such as a low quality oxide. A via hole can be etched into the passivation layer 1060 and the gate insulator 1044 to expose portions of the semiconductor layer 1046. The source/drain metal 1048 can be deposited in the via hole to contact the semiconductor layer 1046. The source/drain metal 1048 can include an Al alloy or a trilayer of Mo/Al/Mo or TiN/Al/TiN. The source/drain metal 1048 can connect with the IMOD display element 1010 so that the TFT can be in electrical communication with the IMOD display element 1010.

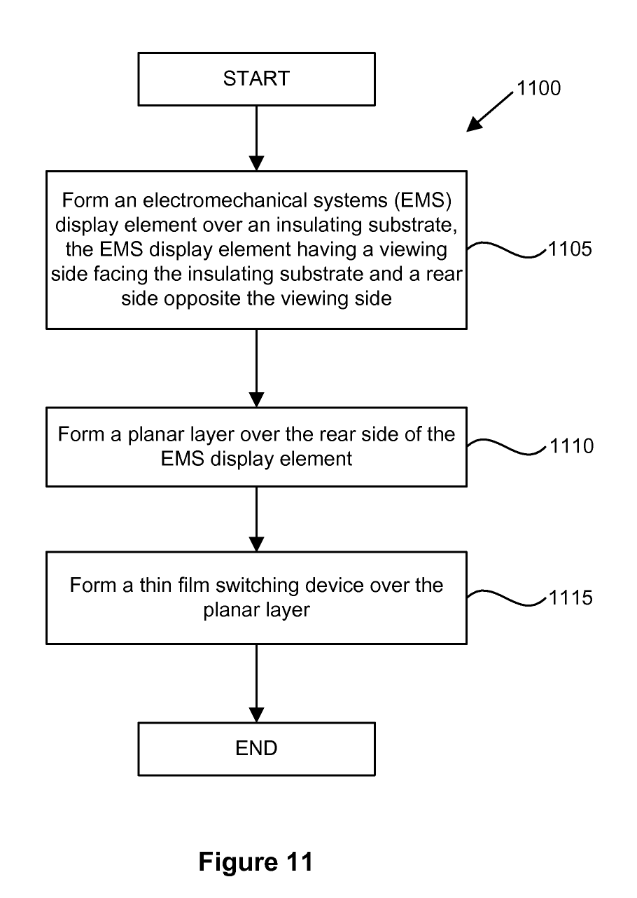

FIG. 11 shows an example of a flow diagram illustrating a method of manufacturing a display apparatus. Some of the blocks may be present in a process for manufacturing IMODs, along with other blocks not shown in FIG. 11. For example, it will be understood that additional processes of depositing underlying or overlying layers, such as sacrificial layers, black mask layers, bussing layers, etc., may be present.

The process 1100 begins at block 1105 where an EMS display element is formed over an insulating substrate. The EMS display element can have a viewing side facing the insulating substrate and a rear side opposite the viewing side. In some implementations, forming the EMS display element can include forming an IMOD, such as an AIMOD. Forming the IMOD can include forming a stationary transparent layer over the insulating substrate and forming a movable reflective layer over the stationary transparent layer to define an optical gap between the stationary transparent layer and the movable reflective layer. The stationary transparent layer can include an optical stack having an absorber layer, as discussed earlier herein. The movable reflective layer can include one or more mirror layers and/or a deformable layer, as discussed earlier herein.

In some implementations, forming the movable reflective layer can be performed after forming the stationary transparent layer. In some implementations, forming the stationary transparent layer can be performed after forming the movable reflective layer. Such a configuration can form an implementation of an inverted IMOD.

The process 1100 continues at block 1110 where a planar layer is formed over the rear side of the EMS display element. As discussed earlier herein, the rear side of the EMS display element can have an uneven surface topography. A planar layer over the rear side of the EMS display element can provide a planar surface for subsequent deposition of layers and/or devices. In some implementations, forming the planar layer can include depositing spin-on glass or polyimide over the rear side of the EMS display element. In some implementations, forming the planar layer can include depositing insulating material over the rear side of the EMS display element and then subsequently applying an appropriate planarization method such as CMP to form the planar layer.

The process 1100 continues at block 1115 where a thin film switching device is formed over the planar layer. In some implementations, the process 1100 can further include forming a base oxide layer over the planar layer before forming the thin film switching device. The thin film switching device can be aligned with and in close proximity to the EMS display element. Additionally, the thin film switching device can be in electrical communication with the EMS display element. In some implementations, forming the thin film switching device can include forming a TFT over the planar layer.

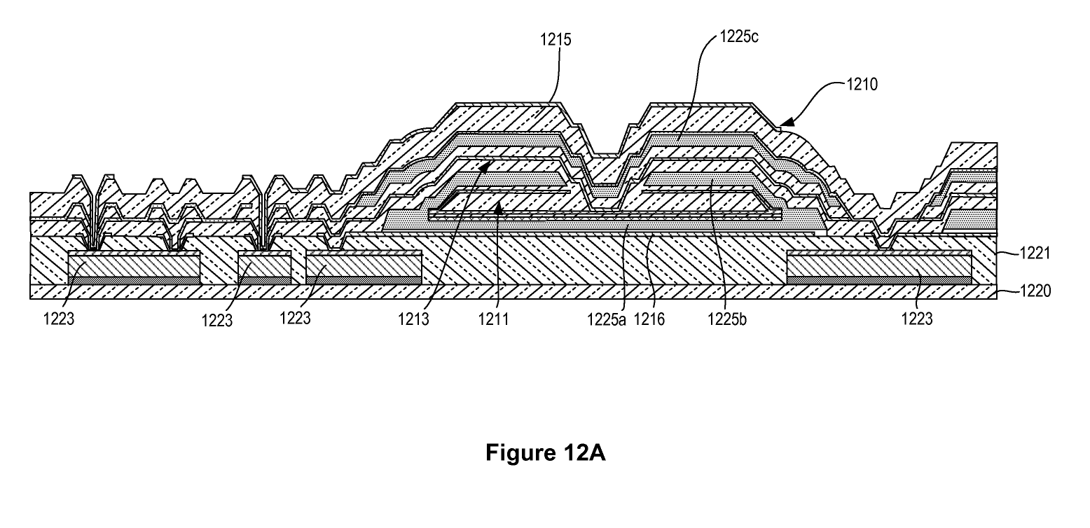

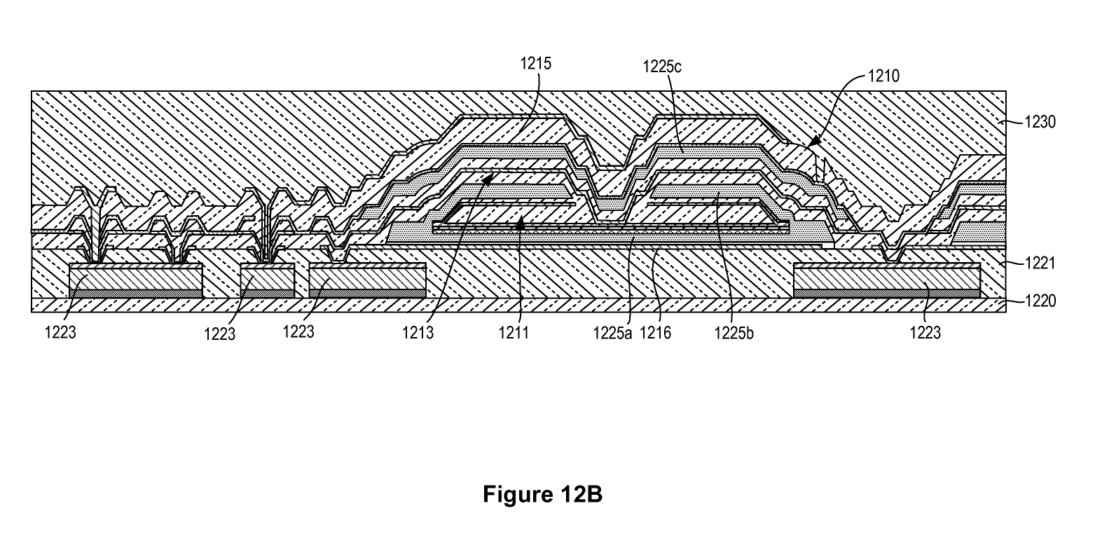

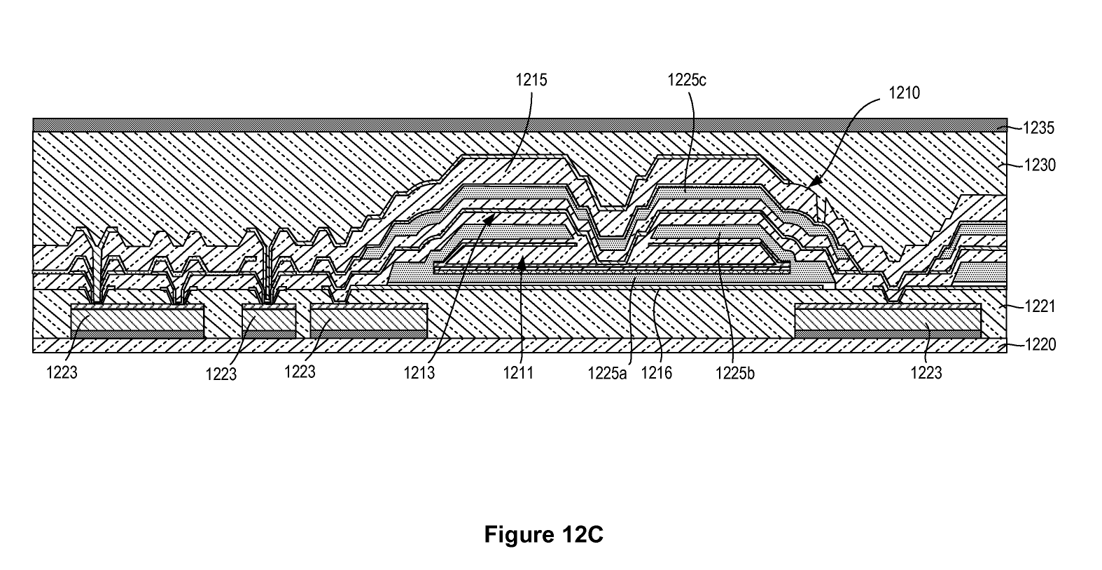

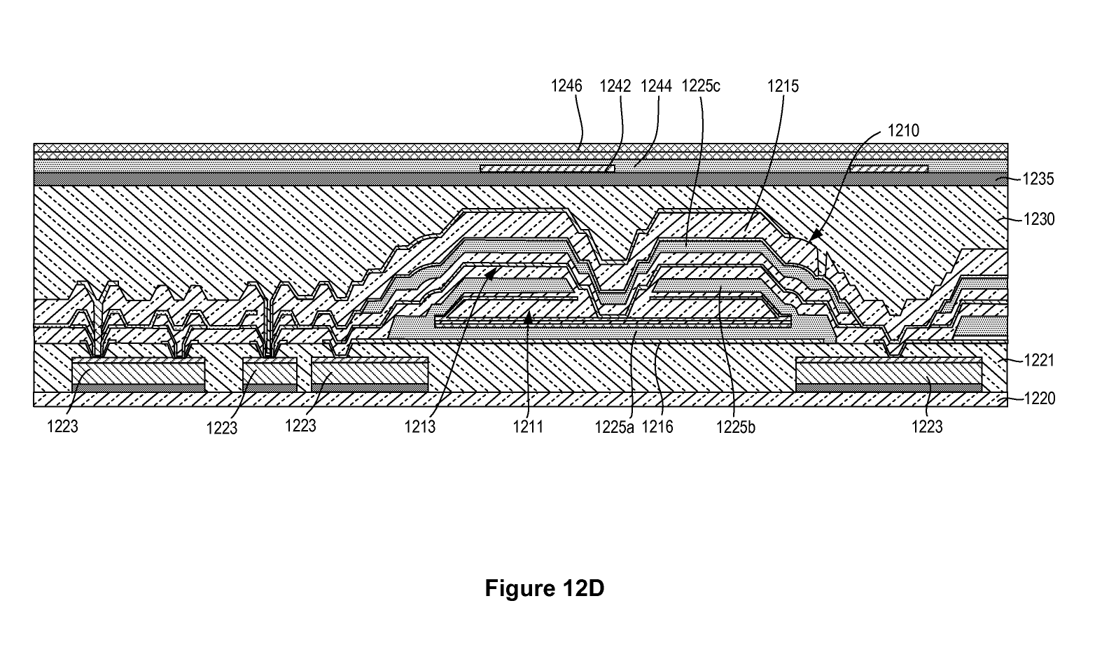

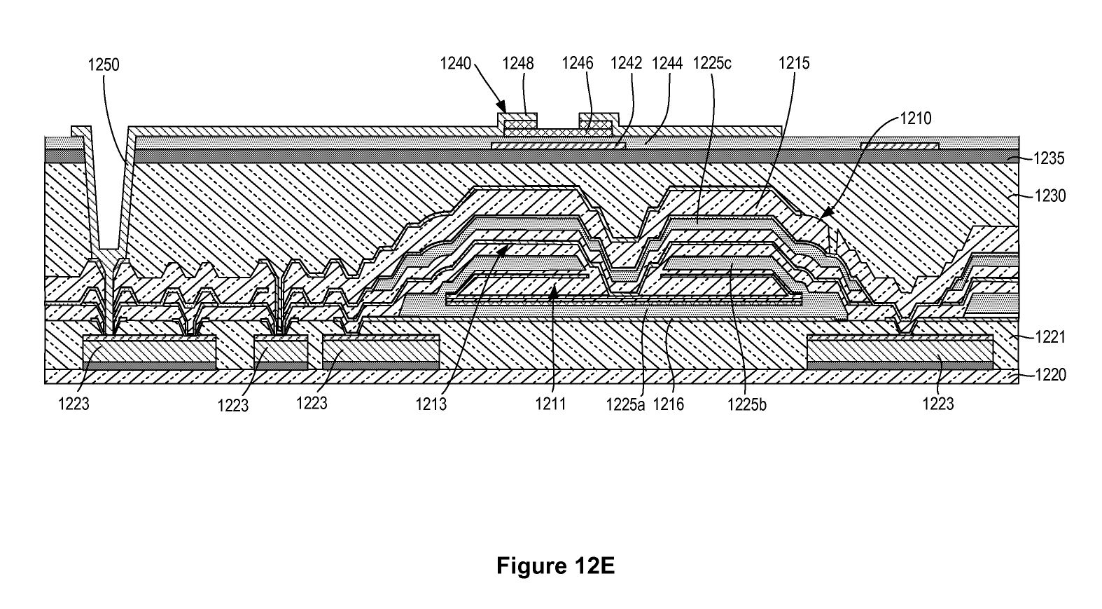

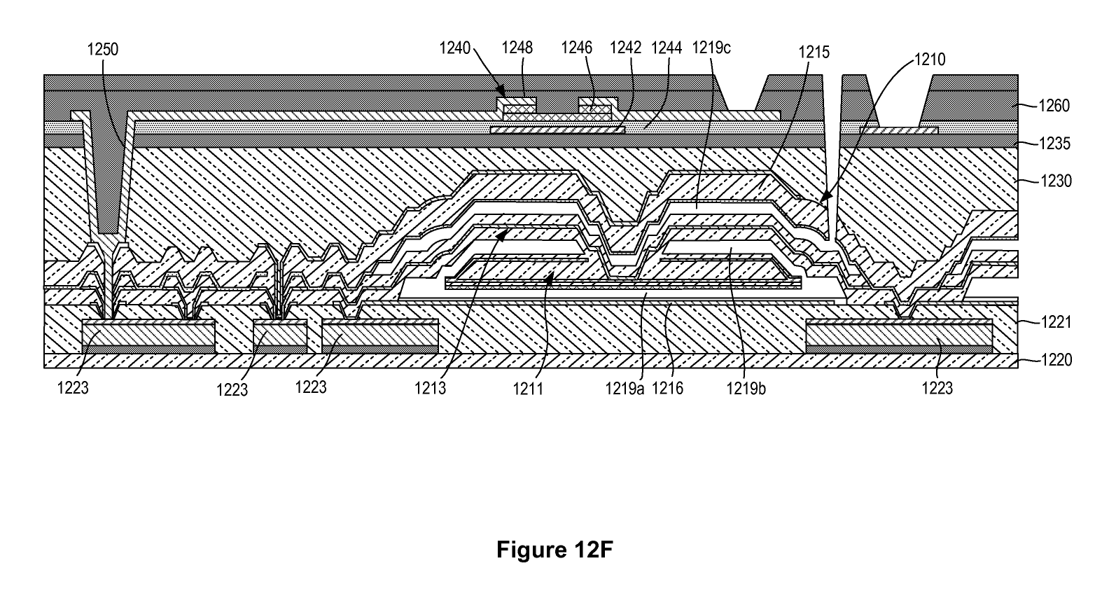

FIGS. 12A-12F show examples of cross-sectional views illustrating various stages of manufacturing a display apparatus with a thin film switching device.

In the example in FIG. 12A, an implementation of an EMS display element 1210 is provided. Each of the layers and sub-layers of the EMS display element can be deposited using techniques known in the art, such as physical vapor deposition (PVD), chemical vapor deposition (CVD), plasma-enhanced chemical vapor deposition (PECVD), atomic layer deposition (ALD), and spin-coating. Additionally, each of the layers and sub-layers can be patterned by masking and etching processes known in the art.

In some implementations, providing the EMS display element 1210 can start with forming black mask structures 1223 over a substrate 1220. The substrate 1220 can be a glass substrate and the black mask structures 1223 can be a multi-layered stack of SiO₂/AlCu/Mo. In some implementations, the black mask structures 1223 can also include MoCr and/or Al₂O₃. The black mask structures 1223 can be patterned using a variety of techniques, including photolithography and dry etching, as discussed earlier herein. A planarization layer 1221 such as spin-on glass may be deposited over the black mask structures 1223.

An optical stack 1216 may be deposited over the planarization layer 1221 and in contact with the black mask structures 1223. The optical stack 1216 can be electrically conductive, partially transparent and partially reflective. The optical stack 1216 may be fabricated, for example, by depositing one or more layers having the desired properties onto the planarization layer 1221. Some examples of the materials usable to form the layers of the optical stack 1216 have been discussed above.

A first sacrificial layer 1225a can be formed over the optical stack 1216. The sacrificial layer 1225a can later be removed (see FIG. 12F) to form the optical gap 1219a. The formation of the first sacrificial layer 1225a over the optical stack 1216 may include deposition of a XeF₂-etchable material such as Mo, a-Si, Ta, Ge, Ti, W, etc. Deposition of the sacrificial layer 1225a may be carried out using various deposition techniques such as PVD, PECVD, thermal CVD, or spin-coating, depending on which sacrificial material is used.

A reflector 1211 may be formed over the sacrificial layer 1225 using one or more deposition steps, along with one or more patterning steps. Formation of the reflector 1211 can include deposition of a highly reflective material such as TiO₂. In some implementations, the highly reflective material can be deposited at a thickness of about 285 Å. Formation of the reflector 1211 can also include deposition of a layer of dielectric material such as SiON or SiO₂ over the layer of highly reflective material. The layer of dielectric material can be deposited at a thickness of about 650 Å. Formation of the reflector 1211 can further include deposition of a conductive material such as AlCu over the layer of dielectric material. The layer of conductive material can be deposited at a thickness of about 300 Å. This can be followed by a relatively thick layer of dielectric material over the layer of conductive material. In some implementations, the relatively thick layer may be formed of SiON and have a thickness of about 5000 Å. In some implementations, a dry etch process can be applied to the relatively thick layer to form a tapered shape. The tapered shape provides an angled sidewall for better step coverage of subsequently deposited layers. A symmetrical set of layers can be formed over the relatively thick dielectric layer. In some implementations, the materials and thicknesses of the layers can be selected so as to create a substantially symmetrical stack in the reflector 1211. In other implementations, one or more of the materials and/or thicknesses of the layers may be varied from the symmetrical arrangement.

A second sacrificial layer 1225b can be formed over the reflector 1211. Formation of the second sacrificial layer 1225b can be carried out as described above with respect to the first sacrificial layer 1225a.

A deformable layer 1213 can be formed over the second sacrificial layer 1225b, and can be connected to the reflector 1211. The deformable layer 1213 may be formed by employing one or more deposition steps. For example, forming the deformable layer 1213 can include deposition of a dielectric layer made of dielectric materials such as SiON and/or SiO₂, followed by a conductive layer made of conductive material such as AlCu, which can be followed by another dielectric layer. Each of the dielectric layers can be deformable and can have a thickness between about 1000 Å and about 3500 Å. The conductive layer can have a thickness of about 300 Å. The materials and thicknesses of the layers in the deformable layer 1213 can be selected to provide a substantially symmetrical arrangement.

A third sacrificial layer 1225c can be deposited over the deformable layer 1213. Formation of the third sacrificial layer 1225c can be carried out as described above with respect to the first and second sacrificial layers 1225a, 1225b.

A stationary element 1215 can be formed over the third sacrificial layer 1225c. In some implementations, the stationary element 1215 can include a conductive layer over a dielectric layer as illustrated in FIG. 12A. In other implementations, the stationary element 1215 can include a conductive layer surrounded by two dielectric layers. The conductive layer can include AlCu and have a thickness of about 300 Å, and each of the dielectric layers can include SiON and/or SiO₂ and have a thickness between about 1 μm and about 3 μm.

In the example in FIG. 12B, a planar layer 1230 can be deposited over the stationary element 1215 using a self-planarizing material. The use of a self-planarizing material can obviate subsequent planarizing processes, such as CMP. In some implementations, the self-planarizing material can include a flowable dielectric material that is a liquid before cure. An example of a suitable flowable dielectric material can include a spin-on dielectric, such as spin-on glass.

A spin-on dielectric refers to any solid dielectric deposited by a spin-on deposition process, which also may be referred to as a spin coating process. In a spin-on deposition process, a liquid solution containing dielectric precursors in a solvent is dispensed on the stationary element 1215. The substrate 1220 may be rotated while or after the solution is dispensed to facilitate uniform distribution of the liquid solution during rotation by centrifugal forces. Rotation speeds of up to about 6000 rpm may be used. Spin-on dielectrics can also include dielectrics formed by dispensing, extruding or casting a liquid solution without subsequent spinning. In some implementations, a spin-on glass can be dispensed with an extrusion mechanism using a blade type nozzle, with no subsequent spinning. The dispensed solution can then be subjected to one or more post-dispensation operations to remove the solvent and form the solid dielectric layer. In some implementations, the dielectric precursor is polymerized during a post-dispensation operation. A spin-on dielectric layer can be an organic or inorganic dielectric layer according to the dielectric precursor used and the desired implementation. In some implementations, multiple layers can be dispensed and cured to build up the spin-on dielectric layer. In some implementations, it can be useful to use a dielectric that, once solidified, has a CTE that is matched with the CTE of the substrate 1220. Hence, in some implementations, the planar layer 1230 can be a spin-on glass layer.

In some implementations, the self-planarizing material can include a high-temperature curable polymer. An example of a suitable high-temperature curable polymer can include a polyimide.

The self-planarizing material can be cured to solidify it, forming a solid dielectric layer with a substantially planarized surface. FIG. 12B shows the planar layer 1230 after solidification. In some implementations, the planar layer 1230 can be cured through a thermal anneal at a temperature of between about 100° C. and about 450° C., such as about 375° C. for a duration of about 1 hour. In some implementations, a single dispensation operation can be performed to form the planar layer 1230. In some implementations, multiple dispensing/post-dispensing operation cycles can be performed to form the planar layer 1230. After curing, the solid planar layer 1230 can form the base material of a subsequently deposited thin film switching device.

In some implementations, instead of self-planarizing material, the planar layer 1230 can be formed by applying planarization techniques on any suitable insulating material. Planarization can include one or more operations, including lapping, grinding, chemical mechanical planarization (CMP), anisotropic dry etching, or another appropriate method.

In certain implementations as illustrated in the example in FIG. 12C, a base layer 1235 can be deposited over the planar layer 1230. The base layer 1235 can serve as a base oxide layer for the subsequent formation of a thin film switching device. In some implementations, the base layer 1235 can be made of SiO₂ and deposited by any deposition techniques known in the art, such as CVD. The base layer 1235 can be conformally deposited so as to be substantially planar with the planar layer 1230. In some implementations, a thin film switching device may be formed directly over the planar layer 1230 without a base layer 1235 in between.

FIGS. 12D and 12E illustrate steps for fabricating a thin film switching device 1240 over the planar layer 1230 and/or base layer 1235. The thin film switching device 1240 can be a thin film diode or any type of TFT known in the art, such as an a-Si TFT. In the example in FIG. 12D, a gate electrode 1242 can be deposited and patterned over the base layer 1235. In some implementations as illustrated in the example in FIG. 12D, the gate electrode 1242 is a bottom gate electrode. In other implementations, such as for poly-Si TFTs, the gate electrode 1242 can be a top gate electrode (not shown). The gate electrode can include Cr, or any number of different metals, such as Al, Cu, Mo, Ta, Nd, W, Ti, and alloys thereof. The gate electrode 1242 can include two or more layers of different metals arranged in a stacked structure. In some implementations, the gate electrode 1242 can be about 1000 Å to about 5000 Å thick.

In addition, a dielectric layer 1244 can be formed over and around the gate electrode 1242. The dielectric layer 1244 may serve as a gate insulator in the TFT 1240. The dielectric layer 1244 can include SiN, or any number of different dielectric materials such as SiO₂, Al₂O₃, SiON, TiO₂, or hafnium oxide (HfO₂). The dielectric layer 1244 can include two or more layers of different dielectric materials arranged in a stacked structure. In some implementations, the dielectric layer 1244 can be about 500 Å to about 5000 Å thick.

A semiconductor layer 1246 can be formed on the dielectric layer 1244. In some implementations, the semiconductor layer 1246 can include a-Si. As illustrated in the example in FIG. 12D, the semiconductor layer 1246 can include a bilayer of doped n-type a-Si formed over intrinsic a-Si. Alternatively, a bilayer of doped p-type a-Si can be formed over intrinsic a-Si in some implementations. The semiconductor layer 1246 can be subsequently patterned and aligned over the gate electrode 1242.

In the example in FIG. 12E, a source/drain metal 1248 can be deposited over the semiconductor layer 1246 and the dielectric layer 1244. In some implementations, the source/drain metal 1248 can include a trilayer of Mo/Al/Mo. A portion of the source/drain metal 1248 can be wet etched using an acid mixture of phosphoric acid, acetic acid, and nitric acid (“PAN”) to expose a portion of the semiconductor layer 1246. The exposed semiconductor layer 1246 can be dry etched to form the a-Si TFT 1240. Additionally, a via structure 1250 can be formed to provide an electrically conductive pathway connecting the source/drain metal 1248 with at least one of the black mask structures 1223. Hence the TFT 1240 can be in electrical communication with the EMS display element 1210.

In the example in FIG. 12F, a passivation layer 1260 can be formed over the thin film switching device 1240. The passivation layer 1260 can include any number of different dielectric materials such as SiO₂, Al₂O₃, TiO₂, SiON, SiN, TiO₂, and HfO₂. In some implementations as illustrated in FIG. 12F, the passivation layer 1260 includes a bilayer of SiO₂ over SiN. One or more openings may be formed in the passivation layer 1260 to expose a portion of the source/drain metal 1248, and one or more openings may be formed in the passivation layer 1260 and dielectric layer 1244 to expose a portion of the gate electrode 1242. Moreover, an etch release hole may be formed to expose the sacrificial layers 1225a, 1225b, and 1225c to an etchant. After etching the sacrificial layers 1225a, 1225b, and 1225c, gaps 1219a, 1219b, and 1219c are formed so that the EMS display element 1210 is movable.

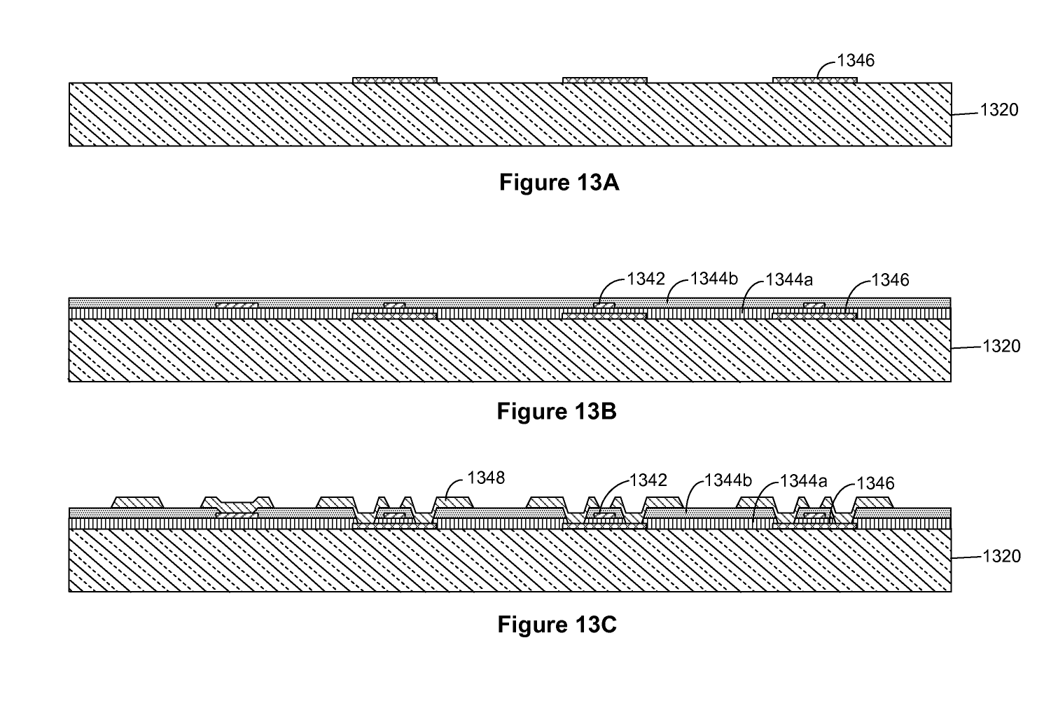

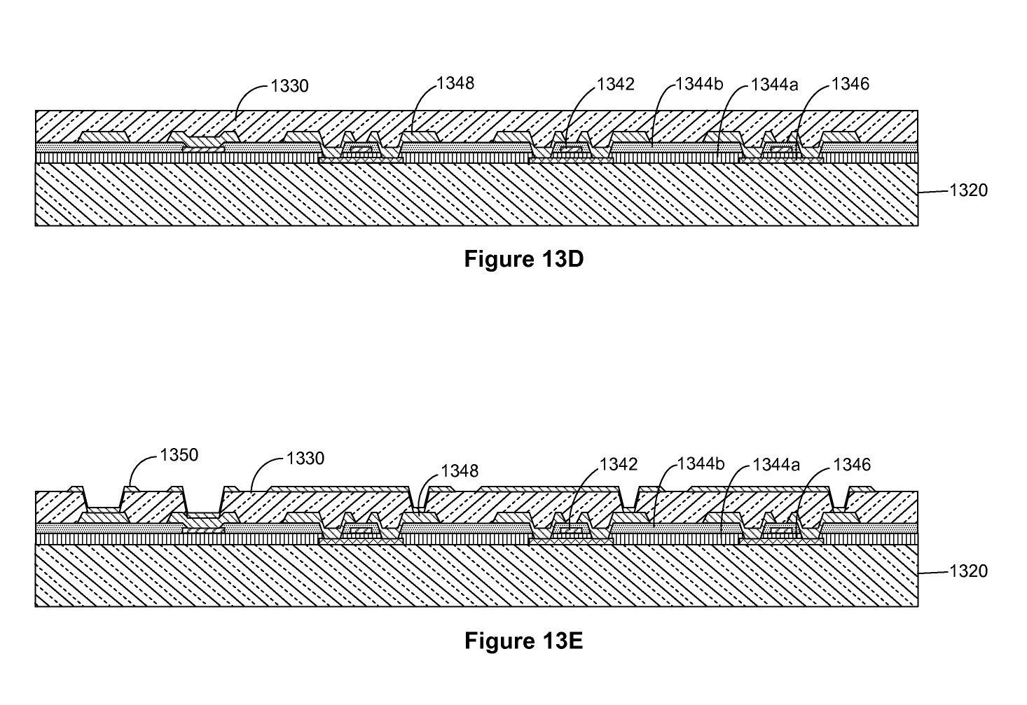

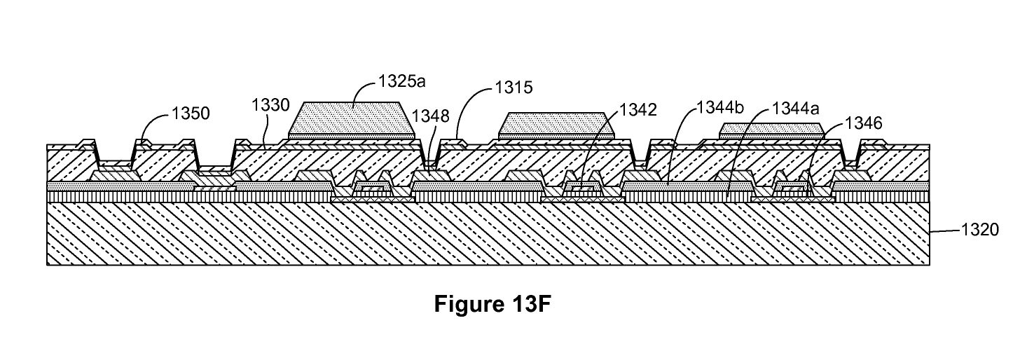

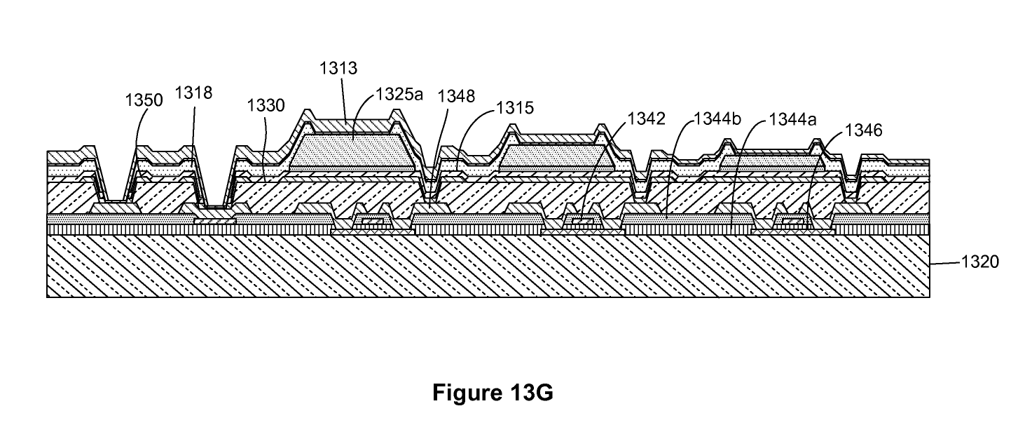

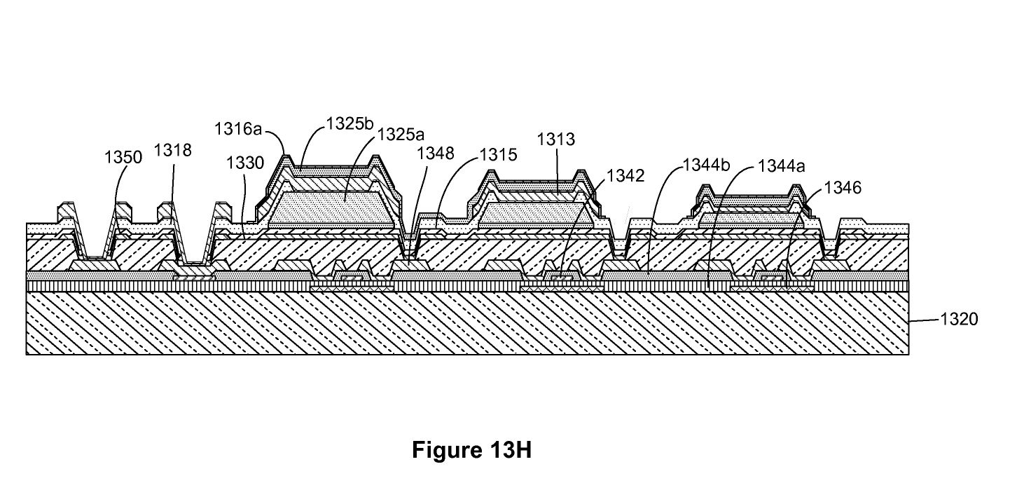

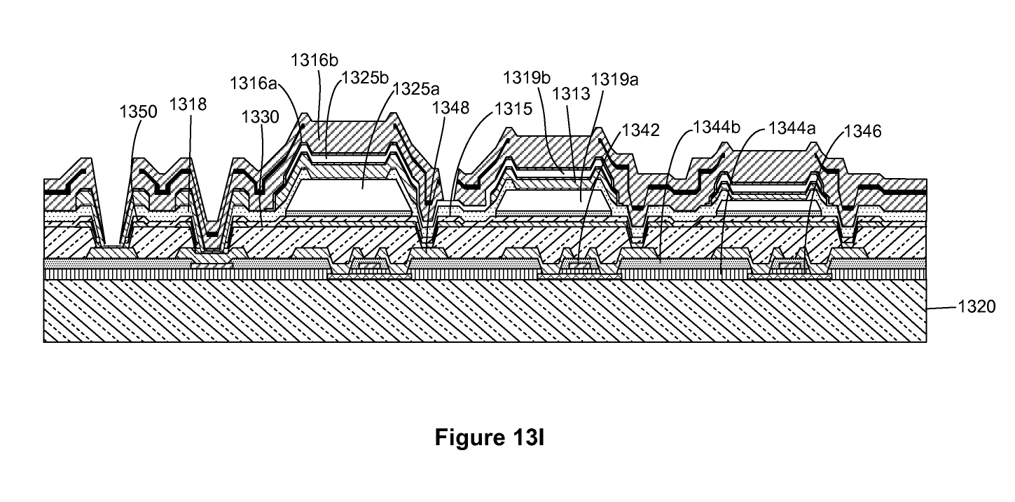

FIGS. 13A-13I show examples of cross-sectional views illustrating various stages of manufacturing another display apparatus with a thin film switching device. In FIGS. 13A-13C, various stages of manufacturing a thin film switching device are illustrated. A semiconductor layer 1346 is deposited and patterned over a substrate 1320 in FIG. 13A. The semiconductor layer 1346 can include but is not limited to a-Si, LTPS, and an oxide semiconductor material such as IGZO and IZO. In FIG. 13B, a gate insulator 1344a and an insulator 1344b may be deposited over the substrate 1320. The gate insulator 1344a can be an oxide layer deposited over the substrate 1320 and the semiconductor layer 1346. The gate insulator 1344a can include a high quality oxide such as SiO₂. A gate metal 1342 can be deposited and patterned over the gate insulator 1344a. The gate metal 1342 can include but is not limited to Cr, Al, Cu, Mo, Ta, Nd, W, Ti, and other suitable metals. The insulator 1344b can be deposited over the gate insulator 1344a and the gate metal 1342. The insulator 1344b can include either a high quality oxide or a low quality oxide. One or more via holes can be etched through the gate insulator 1344a and the insulator 1344b to expose portions of the semiconductor layer 1346 and the gate metal 1342 in FIG. 13C. Furthermore, a source/drain metal 1348 can be deposited in the one or more via holes to contact the exposed portions of the semiconductor layer 1346 and the gate metal 1342 in FIG. 13C. The source/drain metal 1348 can include but is not limited to an Al alloy and a trilayer of Mo/Al/Mo or TiN/Al/TiN. In some implementations, the semiconductor layer 1346, the gate insulator 1344a, the insulator 1344b, the gate metal 1342, and the source/drain metal 1348 collectively form at least a part of a thin film switching device, such as an a-Si TFT, LTPS TFT, semiconductor polymer TFT, and semiconductor oxide TFT.

In FIG. 13D, a planarized layer 1330 such as a layer of spin-on glass can be deposited over the thin film switching device. In some implementations, the planarized layer 1330 can be between about 2500 Å and about 20000 Å in thickness. In FIG. 13E, one or more via holes can be etched into the planarized layer 1330 to expose portions of the source/drain metal 1348 of the thin film switching device, and then subsequently deposited and patterned with a metal 1350 so that the thin film switching device can be in electrical communication with a subsequent EMS display element. The metal 1350 can include but is not limited to MoCr.

In FIGS. 13F-13I, an EMS display element such as a reverse IMOD can be formed over the planarized layer 1330 and over the thin film switching device. In forming the reverse IMOD, it will be understood that various processes for depositing, patterning, and etching of layers and sub-layers may be present. For example, deposition can be achieved by various film deposition processes, such as PVD, PECVD, thermal CVD, ALD, spin-on coating, and electroplating. Patterning techniques, such as photolithography, can be used to transfer patterns on a mask to a layer of material. Etching processes can be performed after patterning to remove unwanted materials. The various layers and sub-layers can include electrodes, dielectric layers, optical layers, sacrificial layers, mechanical layers, mirror layers, posts, buffer layers, bussing layers, black mask layers, etc. in forming the reverse IMOD.

To form the EMS display element, a stationary element 1315 can be deposited over portions of the metal 1350 and portions of the planarized layer 1330 in FIG. 13F. The stationary element 1315 can include at least an optically transparent material, such as SiO₂ and/or AlOₓ. A first sacrificial layer 1325a can be deposited over portions of the stationary element 1315. The first sacrificial layer 1325a can include but is not limited to an etchable material such as Mo or a-Si. Different portions of the sacrificial layer 1325a can be patterned according to different thicknesses, such that the different thicknesses correspond to different wavelengths of light in the visible spectrum produced by the EMS display elements. As such, the resultant EMS display elements can be referred to, for example, as high gap, mid gap, and low gap display elements.

One or more posts 1318 can be deposited and patterned over the stationary element 1315 and the first sacrificial layer 1325a in FIG. 13G. The posts 1318 can be formed of one or more oxides, such as a trilayer of SiO₂/SiON/SiO₂. The posts 1318 can provide separation between the stationary element 1318 and a deformable layer 1313. In FIG. 13G, the deformable layer 1313 is formed over the posts 1318, and can include a dielectric material such as SiON over a reflective material such as an Al alloy. The deformable layer 1313 can have different thicknesses over different portions of the first sacrificial layer 1325a. For example, multiple repetitions of deposition and etch can be used to form the deformable layer 1313 with different thicknesses for high gap, mid gap, and low gap devices. In some other implementations, the deformable layer 1313 of the high gap, mid gap, and low gap display elements can be of substantially the same thickness, with the TFTs associated with the high gap, mid gap, and low gap devices driving different voltages to the respective display elements.

In FIG. 13H, a second sacrificial layer 1325b can be deposited and patterned over the deformable layer 1313. The second sacrificial layer 1325b can include but is not limited to an etchable material such as Mo. A partially reflective layer 1316a can be deposited over the second sacrificial layer 1325b and can include a partially reflective material such as Cr. The partially reflective layer 1316a can have a thickness between about 10 Å and about 100 Å.

In FIG. 13I, a shell layer 1316b can be deposited over the partially reflective layer 1316a and over portions of the posts 1318. The shell layer 1316b can be made of one or more layers of buffer oxide, such as at least 1 μm thick layer of SiO₂. In some implementations, the shell layer 1316a can also include a layer of black resist. Furthermore, a fluorine-based etchant such as XeF₂ can remove the sacrificial layers 1325a and 1325b to release the EMS display element in FIG. 13I. In some implementations, the EMS display element is a reverse IMOD.

The EMS display element can be packaged by various techniques of encapsulation. Encapsulation techniques can include macro-encapsulation and thin film encapsulation. A thin film encapsulation process can involve depositing one or more thin film layers over the EMS display element, while macro-encapsulation involves joining and/or bonding a cover to a device provided on a substrate to form a package. For example, the EMS display element can be encapsulated by a cover glass having a transparent or non-transparent desiccant. In some implementations, the EMS display element can be encapsulated by a thin film encapsulation technique, where one or more layers of optically transparent material can be conformally deposited over the shell layer 1316b and hermetically seal the EMS display element.

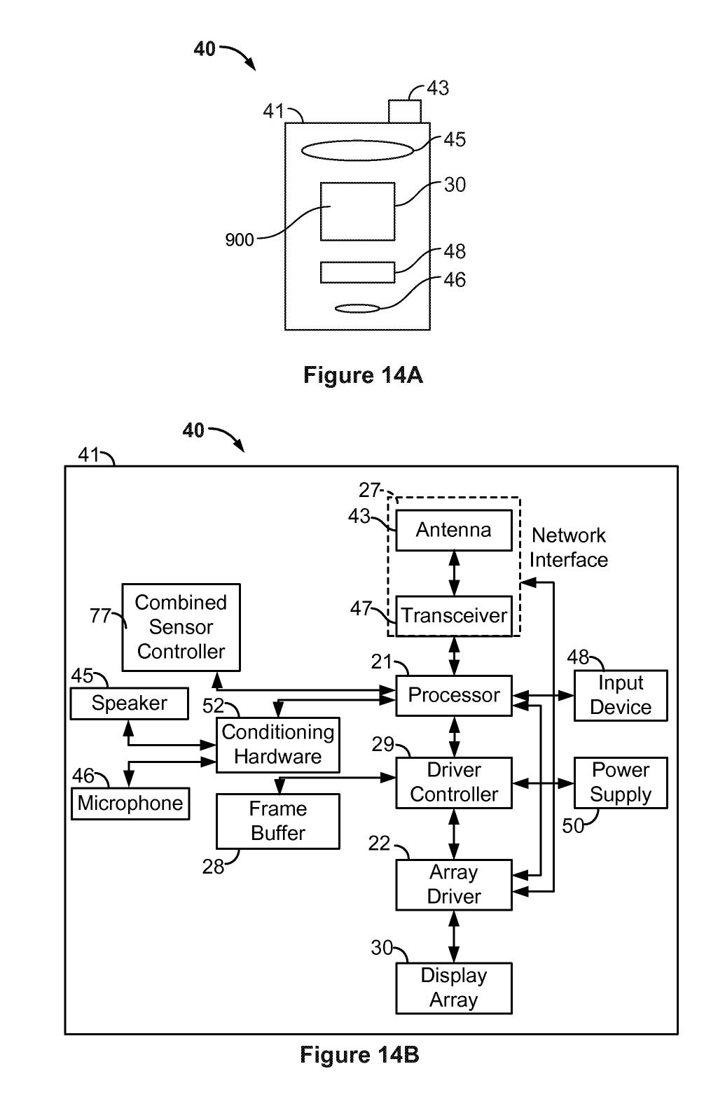

FIGS. 14A and 14B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 14B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those having ordinary skill in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display apparatus, comprising:
a substrate;
an electromechanical systems (EMS) display element over the substrate, the EMS display element having a viewing side facing the substrate and a rear side opposite the viewing side;
a thin film switching device positioned on the rear side of the EMS display element, wherein the thin film switching device is in electrical communication with the EMS display element; and
a planar layer disposed between the EMS display element and the thin film switching device, the planar layer having a planar surface facing the thin film switching device.

2. The apparatus of claim 1, wherein the planar layer includes a self-planarizing material.

3. The apparatus of claim 2, wherein the planar layer includes at least one of a spin-on dielectric and a high-temperature curable polymer.

4. The apparatus of claim 3, wherein the planar layer includes spin-on glass.

5. The apparatus of claim 1, wherein the EMS display element is one of a reflective display element, a transmissive display element, and a self-emitting element.

6. The apparatus of claim 1, wherein the thin film switching device includes at least one of a thin film transistor and a thin film diode.

7. The apparatus of claim 6, wherein the thin film transistor includes amorphous silicon.

8. The apparatus of claim 6, wherein the thin film transistor includes polysilicon.

9. The apparatus of claim 1, wherein the planar layer has a thickness between about 1 μm and about 5 μm.

10. The apparatus of claim 1, wherein the EMS display element is an interferometric modulator (IMOD).

11. The apparatus of claim 10, wherein the IMOD is bistable.

12. The apparatus of claim 10, wherein the IMOD is analog.

13. The apparatus of claim 10, wherein the IMOD includes:
a substrate;
an optical stack over the substrate; and
a movable reflective layer over the optical stack, wherein the optical stack and the movable reflective layer define an optical gap therebetween.

14. The apparatus of claim 1, further including a base layer between the planar layer and the thin film switching device.

15. The apparatus of claim 1, further including:
a display;
a processor that is configured to communicate with the display, the processor being configured to process image data; and
a memory device that is configured to communicate with the processor.

16. The apparatus of claim 15, further including:
a driver circuit configured to send at least one signal to the display; and
a controller configured to send at least a portion of the image data to the driver circuit.

17. The apparatus of claim 15, further including:
an image source module configured to send the image data to the processor.

18. The apparatus of claim 17, wherein the image source module includes at least one of a receiver, transceiver, and transmitter.

19. The apparatus of claim 15, further including:
an input device configured to receive input data and to communicate the input data to the processor.

20. A display apparatus, comprising:
a substrate;
an electromechanical systems (EMS) display element over the substrate;
a thin film switching device disposed between the EMS display element and the substrate, wherein the thin film switching device is in electrical communication with the EMS display element; and
a planar layer disposed between the thin film switching device and the EMS display element, wherein the planar layer has a planar surface facing the EMS display element.

21. The apparatus of claim 20, wherein the thin film switching device includes a thin film transistor.

22. The apparatus of claim 21, wherein the thin film transistor includes at least one of amorphous silicon and polysilicon.

23. The apparatus of claim 20, wherein the planar layer includes spin-on glass.

24. The apparatus of claim 20, wherein the EMS display element is a reverse interferometric modulator (IMOD).

25. A method of forming a thin film switching device integrated display apparatus, comprising:
forming an electromechanical systems (EMS) display element over an insulating substrate, the EMS display element having a viewing side facing the insulating substrate and a rear side opposite the viewing side;
forming a planar layer over the rear side of the EMS display element; and
forming a thin film switching device over the planar layer.

26. The method of claim 25, further including forming a base layer over the planar layer before forming the thin film switching device, wherein the base layer includes silicon dioxide.

27. The method of claim 25, wherein forming the planar layer includes depositing spin-on glass over the rear side of the EMS display element to form the planar layer.

28. The method of claim 25, wherein forming the planar layer includes:
depositing insulating material over the rear side of the EMS display element; and
applying chemical mechanical planarization on the insulating material to form the planar layer.

29. The method of claim 25, wherein forming the thin film switching device includes forming a thin film transistor over the planar layer.

30. The method of claim 25, wherein forming an EMS display element includes forming an interferometric modulator (IMOD), wherein forming the IMOD includes:
forming an stationary transparent layer over the insulating substrate; and
forming a movable reflective layer over the stationary transparent layer to define an optical gap between the movable reflective layer and the stationary transparent layer.

31. A display apparatus, comprising:
a substrate;
an electromechanical systems (EMS) display element having a viewing side facing the substrate and a rear side opposite the viewing side;
a thin film switching device positioned on the rear side of the EMS display element, wherein the thin film switching device is in electrical communication with the EMS display element; and
means for planarizing a surface between the EMS display element and the thin film switching device, the surface facing the thin film switching device.

32. The apparatus of claim 31, wherein the planarizing means includes a self-planarizing material.

33. The apparatus of claim 32, wherein the self-planarizing material includes at least one of a spin-on dielectric and a high-temperature curable polymer.

34. The apparatus of claim 31, wherein the planarizing means has a thickness between about 1 μm and about 5 μm.

35. A display apparatus produced by the method as recited by claim 25.
